(19) United States
(12) Patent Application Publication
(10) Pub. No.: US 2004/0124507 A1
(43) Pub. Date: Jul. 1, 2004

(54) Contact structure and production method thereof

(76) Inventor: Robert Edward Aldaz, Carol Stream, IL (US)

Correspondence Address: MURAMATSU & ASSOCIATES, Suite 225, 7700 Irvine Center Drive, Irvine, CA, 92618, US

(21) Appl. No.: 10/331,564

(22) Filed: Dec. 30, 2002

(51) Int. Cl. H01L 23/495

(52) U.S. Cl. 257/668

(57) ABSTRACT

A contact structure and production method provides an easy and simple way of assembling the contact structure. The contact structure includes a contact substrate for mounting a plurality of contactors in through holes formed thereon, a seed layer formed on a bottom surface of the contact substrate in a manner to cover the through hole, and a solder pad formed on a bottom surface of the seed layer. Under temperature higher than a reflow point of the solder pad, the contactor is inserted into the through hole so that a lower end of the contactor pierces the seed layer and reaches the solder pad, thereby bonding the contactor to the contact substrate.

### FIELD OF THE INVENTION

This invention relates to a contact structure for use in a probe contact assembly for electrical communication such as testing semiconductor devices, and more particularly, to a contact structure which is produced by inserting contactors into the contact substrate while reflowing solder at a bottom of the contact substrate.

### BACKGROUND OF THE INVENTION

In testing high density and high speed electrical devices such as LSI and VLSI circuits, a high performance contact structure such as probe contactors is typically used. The contact structure of the present invention is not limited to the application of testing or burn-in testing, of semiconductor wafers and dice, but also is inclusive of testing and burn-in of packaged semiconductor devices, printed circuit boards and the like. However, for the convenience of explanation, the present invention is described mainly with reference to the semiconductor wafer testing.

FIG. 1 shows an example of a combination of a semiconductor test system and a wafer prober (substrate handler) . The semiconductor test system has a test head 100 which is ordinarily formed in a separate housing and electrically connected to the test system with a bundle of cables 110. The test head 100 and the substrate handler 400 are mechanically as well as electrically connected with each other. The semiconductor wafers to be tested are automatically provided to a test position of the test head 100 by the substrate handler 400.

On the test head, the semiconductor wafer to be tested is provided with test signals generated by the semiconductor test system. The resultant output signals from the semiconductor wafer under test (IC circuits formed on the semiconductor wafer) are transmitted to the semiconductor teat system. In the semiconductor test system, the output signals are compared with expected data to determine whether the IC circuits on the semiconductor wafer function correctly of not.

FIG. 2 shows the connection between the test system and the substrate handler in more detail. The test head 100 and the substrate handler 400 are connected through an interface component 140 consisting of a performance board 120, signal cables such as coaxial cables 124, a pin block structure including a pogo-pin block 130 and contact pins (pogo-pins) 141. The test head 100 includes a large number of printed circuit boards (pin electronics) 150 which correspond to the number of test channels (pins) of the semiconductor test system. Each of the printed circuit boards 150 has a connector 160 to receive a corresponding contact terminal 121 of the performance board 120.

The pogo-pin block 130 is mounted on an upper surface of a frame (not shown) of the substrate handler 400. A large number of pogo-pins 141 are mounted on the pogo-pin block 130 where each of the pogo-pins 141 is connected to the performance board through the cable 124. As is well known in the art, a pogo-pin is a compressive contact pin having a spring therein. The pogo-pin block 130 is to accurately hold the pogo-pins 141 relative to the substrate handler 400.

In the substrate handler 400, a semiconductor device, such as a semiconductor wafer 300 to be tested, is mounted on a chuck 180. In this example, a probe card 170 is provided above the semiconductor wafer 300 to be tested. The probe card 170 has a large number of probe contact targets such as circuit terminals or contact pads in the IC circuit of the semiconductor wafer 300 under test.

Contact pads (electrodes) on the upper surface of the probe card 170 are electrically connected to the pogo-pins 141 when the pogo-pin block 130 is pressed against the probe card 170. Because each pogo-pin 141 is configured to be elastic in the longitudinal direction by the spring therein, it is able to overcome the planarization problem (unevenness of the surface flatness) involved in the probe card, wafer prober frames, or the like. The pogo-pins 141 are also connected to the contact terminals 121 of the performance board 120 through the coaxial cables 124 wherein each contact terminal 121 of the performance board 120 is connected to the printed circuit boards 150 of the test head 100. Further, the printed circuit boards 150 are connected to the semiconductor test system through the cable 110 having several hundreds of inner cables.

The probe contactors 190 contact with the surface (contact targets) of the semiconductor wafer 300 on the chuck 180 to apply test signals to the semiconductor wafer 300 and receive the resultant output signals from the wafer 300. The resultant output signals from the wafer 300 under test are compared with the expected data generated by the semiconductor test system to determine whether the IC circuits on the semiconductor wafer 300 function correctly.

FIG. 3 is a cross sectional view showing an example of probe contact assembly using conventional contact structure. The probe contact assembly is used as an interface between the device under test (DUT) and the test head such as shown in FIG. 2. The pogo-pin block 130 have a large number of pogo-pins 141 to interface between the probe card (space transformer) 260 and the performance board 120 (FIG. 2) through cables 124. At upper ends of the pogo-pins 141, the cables 124 such as coaxial cables are connected to transmit signals to printed circuit boards (pin electronics cards) 150 in the test head through the performance board 120 (FIG. 1 and 2).

The probe card (space transformer) 260 has a large number of electrodes 262 and 265 on the upper and lower surface thereof. The electrodes 262 and 265 are connected through interconnect traces 263 to fan-out the pitch (transform the space) of the contact structure to meet the pitch of the pogo-pins 141 in the pogo-pin block 130. As shown in FIG. 3, in this example, the probe contact assembly includes a conductive elastomer 250 between the probe card 260 and the contact structure. A contact structure is formed of a contact substrate 20 and a plurality of contactors 30 mounted on the contact substrate 20. When assembled, upper portions 33 of the contactors 30 contact the conductive elastomer 250.

The conductive elastomer 250 is an elastic sheet having a large number of conductive wires in a vertical direction. For example, the conductive elastomer 250 is comprised of silicon rubber sheet and multiple rows of metal filaments 252. The metal filaments (wires) 252 are provided in the vertical direction of FIG. 3, i.e., orthogonal to the horizontal sheet of the conductive elastomer 250. An example of pitch between the metal filaments 252 is about 0.05 mm or less and thickness of the silicon rubber sheet is about 0.2 mm. Such a conductive elastomer is produced by, for example, Shin-Etsu Polymer Co. Ltd, Japan, and available in the market.

The contact substrate 20 supports the contactors 30 which also contact an electrode pad 320 on the semiconductor wafer 300 (DUT). A large number of contactors 30 are assembled into the contact substrate 20 in order to test LSIs or VLSIs. Technology for assembling the contactors into the contact substrate is also important because there are several hundreds of contactors which are configured to receive communicate with corresponding contact terminals on the DUT. How effectively and reliably mount the contactors 30 on the contact substrate 20 is one of the important factors for improving test efficiency. Also, it is important to create highly reliable contact structure with high contact performance. Thus, there is a need in the industry of a new method for producing the contact structure efficiently with high reliability and low cost.

### SUMMARY OF THE INVENTION

Therefore, it is an object of the present invention to provide a new assembly method for producing a contact structure to establish electrical communications with contact targets.

It is another object of the present invention to provide a method of producing a contact structure having a large number of contactors mounted on a contact substrate through a soldering process.

One aspect of the present invention is a contact structure for establishing electrical communications with a contact target. The contact structure is assembled through a soldering process. The contact structure includes a contact substrate for mounting a plurality of contactors in through holes formed thereon, a seed layer formed on a bottom surface of the contact substrate in a manner to cover the through hole, and a solder pad formed on a bottom surface of the seed layer. Under temperature higher than a reflow point of the solder pad, the contactor is inserted into the through hole so that a lower end of the contactor pierces the seed layer and reaches the solder pad, thereby bonding the contactor to the contact substrate.

The contactor has a stopper having a flange like shape for defining a vertical position of the contactor on the contact substrate, an upper portion projected from the upper surface of the contact substrate, and a lower portion inserted in the through hole on the contact substrate. A tip of the lower portion of the contactor is within the solder pad, and the solder pad functions as a contact point to contact with the contact target. Alternatively, a tip of the lower portion of the contactor is projected from the solder pad, and the tip of the lower portion functions as a contact point.

Another aspect of the present invention is a method of producing the contact structure noted above. The production method includes the steps of preparing a contact substrate for mounting a plurality of contactors in through holes formed thereon, forming a seed layer on a bottom surface of the contact substrate in a manner to cover the through hole, forming a solder pad on a bottom surface of the seed layer, heating the contactor and the solder pad to temperature higher than a reflow point of the solder pad, inserting the contactor into the through hole so that a lower end of the contactor pierces the seed layer and reaches the soldered pad, and cooling the contactor and the contact substrate, thereby bonding the contactor to the contact substrate.

The step of inserting the contactor into the through hole includes a step of defining a vertical position of the contactor by a stopper having a flange like shape formed on the contactor when the stopper contacts a top surface of the contact substrate. The through hole is formed on the contact substrate through an etching process before forming the seed layer. Alternatively, the through hole is formed on the contact substrate through an etching process after forming the seed layer. The solder pad is formed on the seed layer through an electroplating process.

According to the present invention, the contact structure having a large number of contactors assembled on a single contact substrate can be produced efficiently with high reliability and low cost. The soldering process and the structure of contactors in the present invention achieves an easy and reliable way for assembling the contactors on the contact substrate.

### BRIEF EXPLANATION OF THE DRAWINGS

FIG. 1 is a schematic diagram showing a basic structural relationship between a substrate handler and a semiconductor test system having a test head.

FIG. 2 is a schematic diagram showing an example of detailed structure for connecting the test head of the semiconductor test system to the substrate handler.

FIG. 3 is a cross sectional view showing an example of probe contact assembly as an interface between a semiconductor device under test and a test head of a semiconductor test system.

FIGS. 4A and 4B are cross sectional views showing examples of contact structure in which contactors are inserted in a contact substrate in accordance with the production method of the present invention.

FIGS. 5A-5E are cross sectional views showing a process for producing the contact structure in accordance with the present invention.

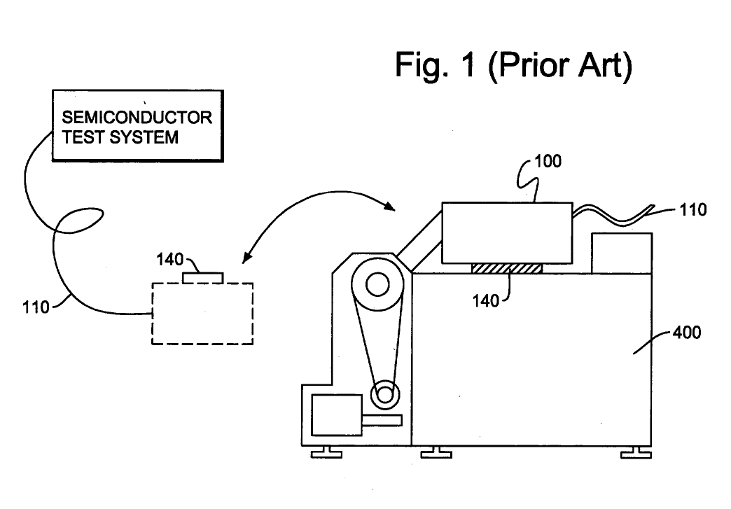

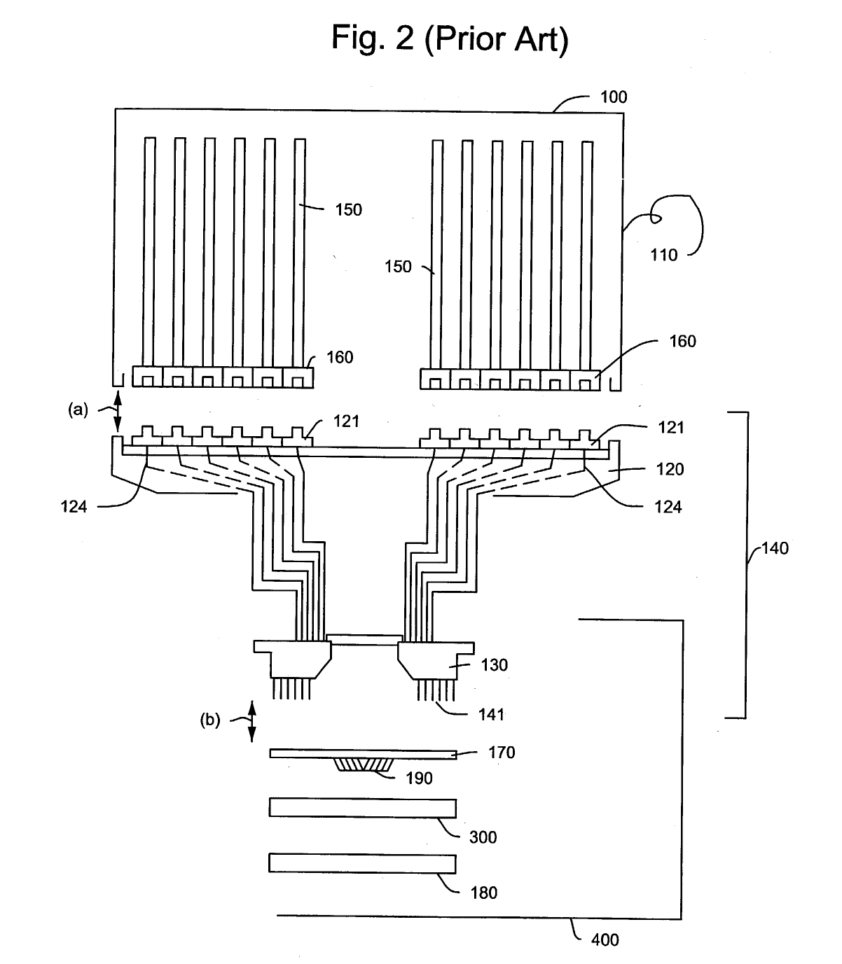

### DETAILED DESCRIPTION OF THE INVENTION

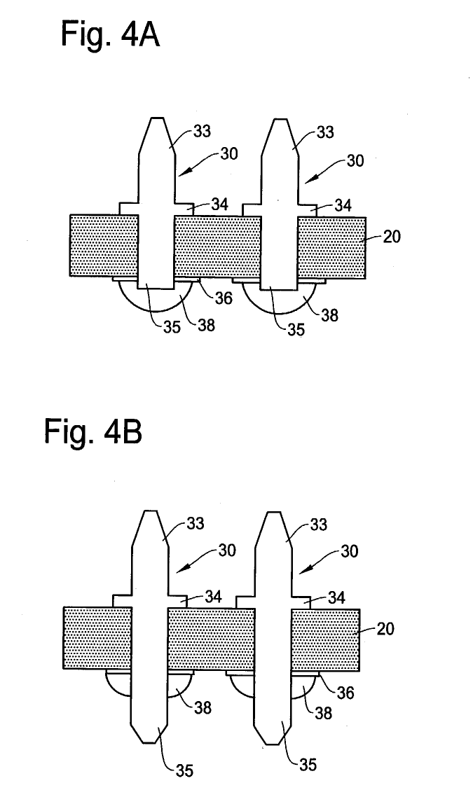

FIGS. 4A and 4B are schematic diagrams showing cross section views of the contact structures assembled in accordance with the present invention. The contact structure is constituted by contactors 30 mounted on a contact substrate 20. The contact substrate 20 is made of silicon, ceramic, glass fiber, alumina, or the like. As shown in FIGS. 4A and 4B, the contactors 30 are inserted in the through holes formed on the contact substrate 20. The contactor 30 has an upper portion 33, a stopper 34 having a flange like structure, and a lower portion 35 inserted in the contact substrate 20. The contactor 30 in FIG. 4B is longer than the contactor of FIG. 4A below the stopper 34.

At the bottom of the contact substrate 20, a solder pad (solder land) 38 is provided which is connected to the lower portion 35 of the contactor 30. As describe in more detail later, when the solder pad 38 reflows, the contactor 30 is inserted in the contact substrate and the lower portion 35 is exposed to the melted solder at the bottom of the contact substrate 20. Thus, the lower portion 35 of the contactor 30 is connected to the solder pad 38 in the manner shown in FIGS. 4A and 4B.

As noted above, in the example of FIG. 4A, the contact structure of the present invention has contactors each being shorter than the contactors in the example of FIG. 4B. Thus, in FIG. 4A, the lower portion 35 of the contactor 30 is within the solder pad 38. In FIG. 4B, the lower portion 35 of the contactor 30 is sufficiently projected from the solder pad 38. In the example of FIG. 4A, the solder pad 38 has two functions: one is to bond the contactor 30 to the contact substrate 20, and another is to function as a contact point to electrically contact with a contact target. In the example of FIG. 4B, however, the role of the solder pad 38 is only to bond the contactor 30 to the contact substrate 20. The lower portion 35 of the contactor 30 functions as a contact point to contact with a contact target.

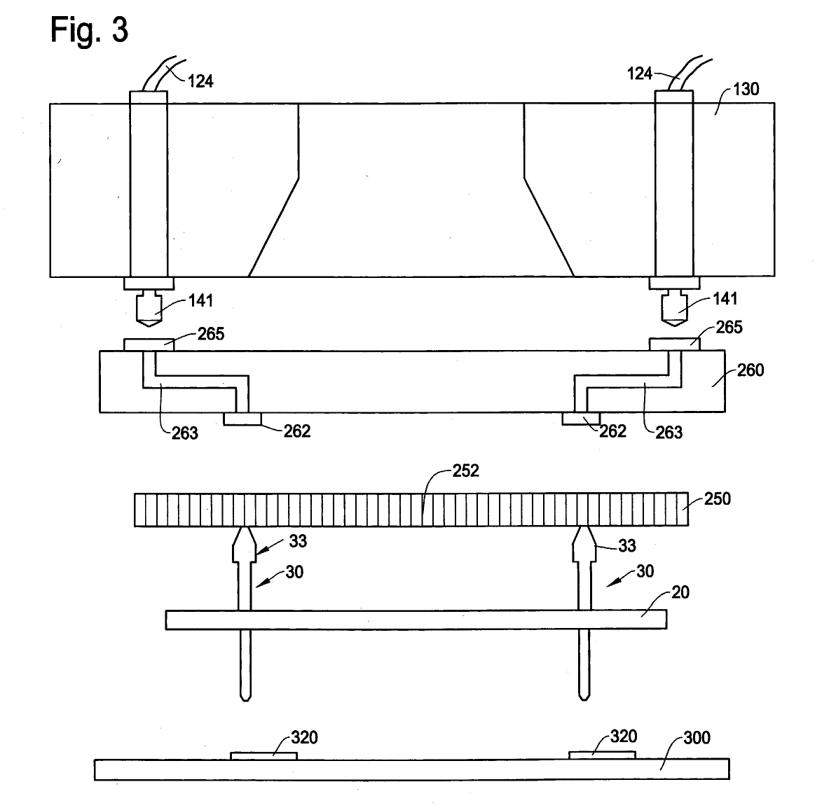

The stopper 34 of the contactor 30 has a function of stopping and positioning the contactor 30 when the contactor 30 is inserted in the through hole from the top of the contact substrate in a vertical direction. When used in a probe contact assembly such a shown in FIG. 3, the upper portion 33 of the contactor 30 contacts the conductive elastomer 250 (or the probe card 260 when the elastomer is not used) directly. Because of the stoppers 34, the height of the contactors 30 is the same with one another, thus, each contactor electrically contacts the conductive elastomer or the probe card reliably at the same time.

The assembly process of the contact structure for mounting the contactors 30 on the contact substrate 20 is explained in the following. This example is directed to the contact structure of FIG. 4A where the lower portion 35 is within the solder pad 38, although the same process can be used for assembling the contact structure of FIG. 4B.

Several methods for soldering the contactor 30 on the bottom, surface of the substrate 20 to the solder pad (solder land) on the bottom surface are possible. One of the methods is to use a seed layer with solder pad on the bottom surface of the substrate.

Typically, the contact substrate 20 is made of silicon or ceramic. When producing the contact structure on a bare board of the contact substrate, a seed layer is formed on the through hole of the contact substrate where the contactor 30 should be inserted. The seed layer is shaped in round, square, or the like, as a pad to perform a solder layer (solder pad) 38 through an electrical plating. The through hole is created on the contact substrate 20 by an etching process such as a deep trench etching method.

The seed layer (seed) is formed either before creating the through hole or after creating the through hole. At any rate, the seed is formed in a manner to cover the through hole at the bottom of the contact substrate 20. The diameter of the seed layer is larger than the diameter or other appropriate size of the contactor 30. Preferably, the thickness of the seed layer is small enough so that the contactor 30 is able to brake the seed layer when inserted in the through hole at the final stage of assembly.

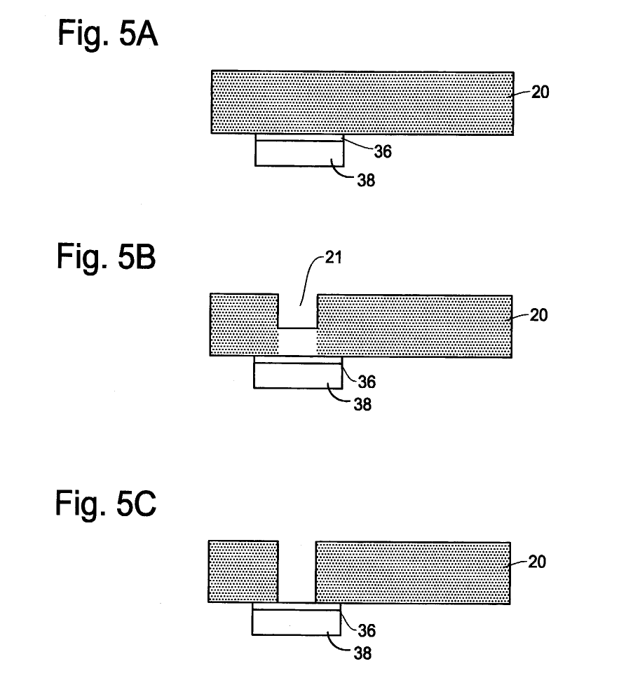

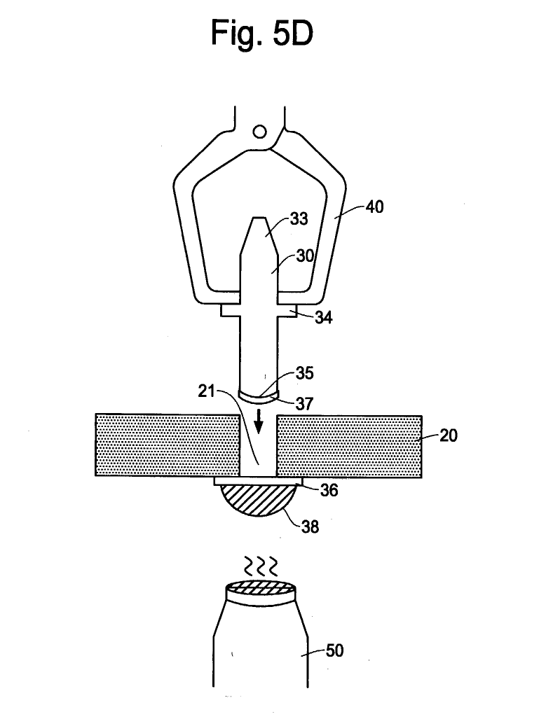

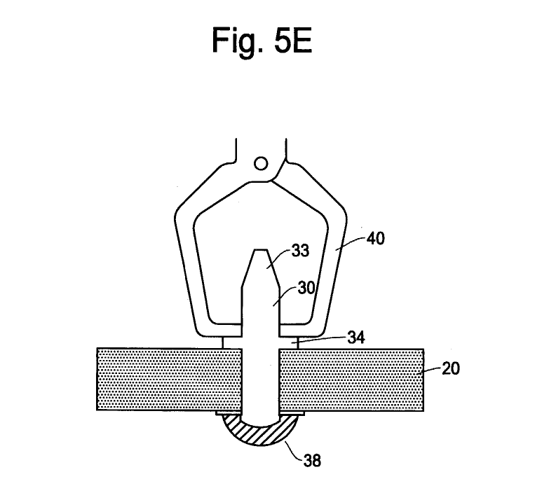

For example, the seed layer is made of nickel. An example of the seed layer is shown in FIG. 5A. A seed layer (seed) 36 is located at a predetermined position on the contact substrate 20 where the through hole is formed. Although only one of them is shown, in an actual application, a large number of seeds 36 are prepared on the contact substrate 20 to make a large number of through holes and solder pads 38. The positions of the seeds 36 are determined by the positions of the contact targets such as contact pads 320 on the semiconductor wafer 300 to be tested (FIG. 3).

In the example of FIGS. 5A-5E, the seed 36 is already formed on the bottom surface of the contact substrate, although the seed 36 can be formed after forming the through holes. Further, in this example, the solder pad 38 is created on the seed 36 although the solder pad 38 can be produced on the seed 36 after forming the through hole 21 on the contact substrate 20. As noted above, the solder pad 38 is produced through an electroplating process, however, various other ways can also be used.

After the preparation of the seed 36 with the solder pad 38 on the contact substrate 20, an etching process is applied to the contact substrate 20 in order to make a through hole in the position where the seed 36 is located. By etching a part of silicon of the contact substrate 20, a hole 21 is formed as shown in FIG. 5B. Because the etching agent is selected so that the etching effects only on the material (ex. silicon) of the contact substrate 20, the etching process stops on the surface of the seed 36 (because of the property of etching resist).

As a result, the through hole 21 is made on the contact substrate 20 as shown in FIG. 5C although the through hole 21 is closed by the seed 36 and solder pad 38. The diameter of the through hole 21 is determined so that the contactor 30 below the stopper 34 can snugly fit therein. In this manner, all the through holes 21 are created on the contact substrate 20 corresponding to all the seeds 36 on the bottom surface of the contact substrate 20.

After the process of making the through holes 21 on the contact substrate 20, the process of assembling the contactors 30 on the contact substrate 20 starts. This process is achieved through soldering. There are two components that should be heated and the temperature has to be higher than the reflow point of the solder pad 38 during the assembly process.

Various methods can be used for heating the components involved in the contact structure. One is to place the whole contact substrate 20 and other components including the contactors 30 in a thermal chamber or oven. The temperature inside the chamber is kept higher than the melting point of solder. Then, a special tool such as a robot hand in the thermal chamber picks the contactors 30 and inserts the same in the contact substrate 20.

Another method is a one which uses a traditional heating tool such as a heat gun. This assembly process is explained with reference to FIGS. 5D and 5E. Before starting the assembly process, the contactor 30 and the solder pad 38 are heated so that the temperature is higher than the reflow point of the solder pad 38. As a result, the shape of the solder pad 38 under the seed 36 will become like a half sphere as shown in FIG. 5D. A tip 37 at the lower portion 35 of the contactor 30 is also heated sufficiently to make the soldering easier when inserted in the through hole 21.

To hold the contactor 30 firmly, a clamping tool 40 such as shown in FIG. 5D is preferably used. Preferably, the contacting surface of the clamping tool 40 has low thermal conductivity to maintain the temperature of the contactor 30 higher than the reflow temperature of the solder during the assembly process. In the assembly process, the clamping tool 40 clamps and positions the contactor 30 over the through hole 21 and then presses the contactor 30 downward in the through hole 21.

The lower tip 37 of the contactor 30 passes through the through hole 21 and reaches the surface of the seed 36. Then, the clamping tool further pushes the contactor 30 downward. As a result, the lower tip 37 of the contactor 30 pierces the seed 36 so that the lower end 35 of the contactor 30 is soldered to the solder pad 38 which is in the shape of a half sphere. As mentioned, the thickness of the seed 36 is thin enough to make the contactor 30 to break the seed 36 relatively easily to reach the solder pad 38.

FIG. 5E shows the status of the process just before finishing the inserting process. The stopper 34 has a function for positioning the contactor 30 in the vertical direction by contacting the top surface of the contact substrate 20. As a result, the height of the upper portion 33 from the top surface of the contact substrate 20 is kept in the same height as other contactors. After the clamping tool 40 finishes inserting the contactor 30 into the through hole of the contact substrate 20, the contact structure is cooled down and the assembly process is completed.

In the foregoing example, the clamping tool 40 as shown in FIG. 5D and FIG. 5E clamps only one contactor 30. However, different tools to pick and insert a large number of contactors can be easily considered if the idea of the insert tool 40 is extended. Thus, the clamping tool may be replaced with a robot having a plurality of hands to grab many contactors at the same time. The motion of the robot hands to pick, positioning and insert the contactors into through holes may be controlled by a microcontroller. Then, the efficiency of the production for the contact substrate is expected to be improved.

As described above, according to the present invention, the contact structure having a large number of contactors assembled on a single contact substrate can be produced efficiently with high reliability and low cost. The soldering process and the structure of contactors in the present invention achieves an easy and reliable way for assembling the contactors on the contact substrate.

Although only a preferred embodiment is specifically illustrated and described herein, it will be appreciated that many modifications and variations of the present invention are possible in light of the above teachings and within the purview of the appended claims without departing the spirit and intended scope of the invention.

What is claimed is:

1. A contact structure for establishing electrical communications with a contact target, comprising:
a contact substrate for mounting a plurality of contactors in through holes formed thereon;
a seed layer formed on a bottom surface of the contact substrate in a manner to cover the through hole; and
a solder pad formed on a bottom surface of the seed layer;
wherein, under temperature higher than a reflow point of the solder pad, the contactor is inserted into the through hole so that a lower end of the contactor pierces the seed layer and reaches the solder pad, thereby bonding the contactor to the contact substrate.

2. A contact structure as defined in claim 1, wherein the contactor has a stopper having a flange like shape for defining a vertical position of the contactor when inserted in the through hole by contacting with a top surface of the contact substrate.

3. A contact structure as defined in claim 1, wherein the contactor has a stopper having a flange like shape for defining a vertical position of the contactor on the contact substrate, an upper portion projected from the upper surface of the contact substrate, and a lower portion inserted in the through hole on the contact substrate.

4. A contact structure as defined in claim 3, wherein a tip of the lower portion of the contactor is within the solder pad, and wherein the solder pad functions as a contact point to contact with the contact target.

5. A contact structure as defined in claim 3, wherein a tip of the lower portion of the contactor is projected from the solder pad, and wherein the tip of the lower portion functions as a contact point to contact with the contact target.

6. A method of producing a contact structure for establishing electrical communications with a contact target, comprising the following steps of:
preparing a contact substrate for mounting a plurality of contactors in through holes formed thereon;
forming a seed layer on a bottom surface of the contact substrate in a manner to cover the through hole;
forming a solder pad on a bottom surface of the seed layer;
heating the contactor and the solder pad to temperature higher than a reflow point of the solder pad;
inserting the contactor into the through hole so that a lower end of the contactor pierces the seed layer and reaches the soldered pad; and
cooling the contactor and the contact substrate, thereby bonding the contactor to the contact substrate.

7. A method of producing a contact structure as defined in claim 6, wherein said step of inserting the contactor into the through hole includes a step of defining a vertical position of the contactor by a stopper having a flange like shape formed on the contactor when the stopper contacts a top surface of the contact substrate.

8. A method of producing a contact structure as defined in claim 6, wherein the through hole is formed on the contact substrate through an etching process before forming the seed layer.

9. A method of producing a contact structure as defined in claim 6, wherein the through hole is formed on the contact substrate through an etching process after forming the seed layer.

10. A method of producing a contact structure as defined in claim 6, wherein the solder pad is formed on the seed layer through an electroplating process.

11. A method of producing a contact structure as defined in claim 6, wherein the lower end of the contactor is inserted in the through hole so that the lower end is within the solder pad, whereby the solder pad functions as a contact point to contact with the contact target.

12. A method of producing a contact structure as defined in claim 6, wherein the lower end of contactor is inserted in the through hole so that the lower end is projected from the solder pad, whereby the lower end of the contactor functions as a contact point to contact with the contact target.
